(19) United States
(12) Patent Application Publication
(10) Pub. No.: US 2023/0144913 A1
(43) Pub. Date: May 11, 2023

(54) TRANSPORT SYSTEM FOR TRANSPORTING MATERIAL TO BE SOLDERED THROUGH A SOLDERING APPARATUS, AND SOLDERING APPARATUS WITH LATERALLY MOVABLE MIDDLE SUPPORT

(71) Applicant: ERSA GmbH, Wertheim (DE)

(72) Inventor: Lothar Endreß, Wertheim (DE)

(73) Assignee: ERSA GmbH, Wertheim (DE)

(21) Appl. No.: 17/983,760

(22) Filed: Nov. 9, 2022

(30) Foreign Application Priority Data
Nov. 9, 2021 (DE) 20 2021 106 103.0

(51) Int. Cl. B23K 37/02; B65G 37/00; B23K 37/047

(52) U.S. Cl. CPC B23K 37/0211; B23K 37/047; B65G 37/005

(57) ABSTRACT

A transport system for transporting material to be soldered through a soldering apparatus, and soldering apparatus with laterally movable middle support. The transport system for transporting the material to be soldered through the soldering apparatus, includes at least one transport track extending in the transport direction in which the material to be soldered is transportable in a transport plane in the transport direction, wherein the transport track includes two transport bars extending in the transport direction and at least one middle support with a middle bar extending in the transport direction. The middle bar has a revolving conveying means with folding elements, and the conveying means provides a feed in the transport direction and a return counter to the transport direction. The folding elements are displaceable between a support position and a folded position. Further provided is an adjusting device for transverse adjustment of the at least one middle support in a transverse direction running transversely to the transport direction, characterized in that a distance A between an underside of at least one transport bar facing away from the transport plane and the transport plane is smaller than a distance B between an upper side of the at least one middle support facing the transport plane and the transport plane, and that the adjustment device is designed such that the middle support with folding elements is movable in the folded position in the transverse direction underneath the at least one transport bar into a parked position provided laterally next to the transport bar.

### CROSS-REFERENCE TO RELATED APPLICATION

The present application relates and claims priority to German Patent Application No. 20 2021 106 103.0, filed Nov. 9, 2021, the entirety of which is hereby incorporated by reference.

### BACKGROUND

The invention relates to a transport system for transporting material to be soldered, in particular of populated printed circuit boards, by means of a soldering apparatus, having at least one transport track extending in the transport direction, in which the material to be soldered can be transported in the transport direction in a transport plane, wherein the transport track comprises two transport bars extending in the transport direction and at least one middle support with a middle bar extending in the transport direction, wherein the middle bar has a circulating conveying means with folding elements, wherein the conveying means provides a feed in the transport direction and a return counter to the transport direction, and wherein the folding elements are displaceable between a support position, in which they are folded up towards the transport plane, for supporting the material to be soldered, and with an adjusting device for transverse adjustment of the at least one middle support in a transverse direction running perpendicular to the transport direction.

Such transport systems convey the particular material to be soldered in the transport direction by contacting the edges running parallel to the transport direction. For this purpose, conveying means are provided in the transport bars, for example, in the form of chains or belts. The transport bars can have a length of several meters and be composed of several rail sections. Furthermore, it is known, in addition to the two outer transport bars which support the material to be soldered at the edges, to provide middle support with a middle bar which supports the material to be soldered in the middle region. Middle supports are advantageous in particular when comparatively large printed circuit boards or goods carriers are soldered or dried. They prevent the material to be soldered from bending or sagging in the middle region, which can occur, in particular, due to the heating of the material to be soldered, and therefore ensure functionally reliable transport.

The invention also relates to a soldering apparatus, in particular a reflow soldering apparatus for continuous soldering of material to be soldered, or a drying system for drying populated printed circuit boards, in which material to be soldered can be transported along a transport direction.

Reflow soldering apparatus are used to solder so-called SMD components (surface mounted devices) onto the surface of printed circuit boards by means of soldering paste. The soldering paste, which is in particular a mixture of metal solder granules, flux and pasty components, is applied or printed onto the surface of the printed circuit boards for reflow soldering. Subsequently, the components to be soldered are placed into the soldering paste. In the reflow soldering process, the material to be soldered, i.e., the assembly consisting of a printed circuit board, soldering paste and components to be soldered, is preheated along the process channel in a preheating zone, and heated in a soldering zone to a temperature above the melting point of the soldering paste. As a result, the soldering paste melts, and the soldering joints are formed. In a cooling zone, if one is present, the material to be soldered is cooled until the melted solder solidifies before it is removed from the reflow soldering apparatus.

With reflow soldering apparatus, the process channel is generally formed by two channel halves, an upper and a lower channel half. The lower channel half is provided in or on a base body, and the upper channel half is provided in or on a hood. Further components such as, for example, nozzle plates, fan units, air ducts conducting the process gas, filter elements and/or cooling elements, are generally provided in or on the process channel, or in or on the base body and in or on the hood. Overall, a desired temperature profile is thereby provided along the transport direction in the process channel, wherein the process gas is blown into the process channel, sucked out therefrom, in particular cooled in the cooling zone, cleaned, and fed back to the process channel.

A soldering apparatus with transport units for transporting material to be soldered is known from DE 10 2019 128 780 A1 and DE 10 2005 055 283 A1. Furthermore, it is known from DE 10 2019 125 981 A1 to provide a transport system for transporting material to be soldered through a soldering apparatus with two transport tracks running parallel to one another and extending in the transport direction, wherein each of the transport tracks comprises at least two transport bars running parallel to one another and extending in the transport direction. In order to be able to accommodate different sizes and, in particular, different widths of material to be soldered, it is also known that the transport tracks are designed to be adjustable transversely to the transport direction.

It has been shown that middle supports, in particular when they are not needed, can have a disadvantageous effect on the soldering process. In particular, it cannot be ruled out that the middle supports shield a heat transfer towards the material to be soldered so that the warm air flow striking the material to be soldered is inhomogeneous, and therefore adversely affect the soldering process.

### SUMMARY OF THE INVENTION

The object of the invention is to provide a transport system for transporting material to be soldered through a soldering apparatus, and a soldering apparatus with a transport system in which a middle support can be used, but should not negatively affect the soldering process — in particular when said middle support is not needed.

This object is achieved by a transport system. Consequently, it is provided in particular that the distance A between an underside of at least one transport bar facing away from the transport plane and the transport plane is smaller than the distance B between an upper side of the at least one middle support facing the transport plane and the transport plane, and that the adjustment device is designed such that the middle support with folding elements in the folded position is can be moved in the transverse direction underneath the at least one transport bar into a parked position provided laterally next to the transport bar.

Such an arrangement has the advantage that the at least one middle support, when not needed, can be completely moved laterally out of the region below the soldering plane under the transport bars or transport bars. Due to the fact that the respective middle support is thus not located below the material to be soldered and, in particular, also not below the transport bars, but laterally next to the transport bars on the side of the transport bars facing away from the material to be soldered in the parked position, the particular middle support does not have any negative effects on the heat transfer towards the printed circuit board, and therefore also has no effect on the soldering result.

With the adjusting device, the middle supports can consequently be moved out of the particular process region transversely to the transport direction until it is ensured that they do not negatively influence the soldering result.

According to the invention, the folding elements, which can in particular be designed as folding spring tabs, are such that they support the material to be soldered in the support position from below. In the folded position, the folding elements are preferably oriented running in the horizontal direction so that the middle support together with the folding elements can be moved in the transverse direction underneath the respective transport bar.

The parked position is selected, in particular, such that the middle support is arranged in the parked position, in particular, in the horizontal direction and in the vertical direction at a distance from the transport bar under which it is moved into the parked position.

It is further advantageous if two or more transport tracks are provided and if an independent separate middle support is provided for each of the transport tracks, wherein each of the middle supports is adjustable in the transverse direction with an adjusting device independently of the other middle support such that each middle support can be moved into a parked position. The parked positions can each be provided laterally next to the particular transport bar on which the side of the transport bar facing away from the particular material to be soldered. It is also conceivable that the middle supports can be moved in different directions into the particular parked position, or in the same directions into the particular parked position. In particular, when two transport tracks and two middle supports are provided, it is advantageous to move one middle support in the one transverse direction, and the other middle support in the opposite transverse direction, into the particular parked position laterally next to the particular outer transport bar.

Furthermore, it is advantageous if the individual middle supports are each present in an independent transport track, or together in one of the two transport tracks, for supporting the particular material to be soldered. In the transport tracks, the folding elements in the feed are in particular in the support position in order to support the particular material to be soldered. For example, it can be provided that both middle supports support the same transported good, in particular when the transported good is comparatively wide. On the other hand, it is conceivable that each of the middle supports supports material to be soldered in an independent transport track independently of the other middle support.

Furthermore, it can be provided that two middle supports are provided, and that the folding elements of the particular middle supports laterally contact the particular conveying means, the folding elements of which are provided on sides of the two middle supports facing away from one another or on sides facing one another. In particular when two middle supports are provided, it is advantageous if the folding elements are provided on the particular middle support on sides facing away from one another.

Furthermore, it is advantageous if, in the parked position, the folding elements are in the folded position in the feed and/or return. This saves installation space upward, so that the vertical distance between the transport bars and the particular middle support can be comparatively small.

Furthermore, it is advantageous if at least one folding device is provided which is provided for displacing the folding elements between the support position and the folded position. Such a folding device can, in particular, be actuated externally to displace the folding elements.

Advantageously, at least one folding device is configured in such a way that, before or during the movement of the at least one middle support into the parked position, the folding elements are in the folded position in the feed, and preferably also in the return. This ensures that, when the middle support is moved underneath the particular transport bar into the parked position, the folding elements are not in their vertical position but rather in their, in particular, horizontal folded position.

Furthermore, it is advantageous if the at least one folding device is configured such that the folding elements are always in the folded position in the return. This ensures that installation space can be saved vertically downward, since the folding elements are, in particular, in the horizontal folding position.

The aforementioned object is also achieved by a soldering apparatus in which material to be soldered can be transported along a transport direction, wherein such a soldering apparatus comprises a transport system according to the invention.

### BRIEF DESCRIPTION OF THE DRAWINGS

Further details and advantageous embodiments of the invention can be found in the following description with which exemplary embodiments of the invention are described and explained in more detail.

In the drawings:

FIG. 1 shows a side view of a reflow soldering apparatus;

FIG. 2 shows a cross section of a first transport system; and

FIG. 3 shows a cross section of a second transport system.

### DETAILED DESCRIPTION

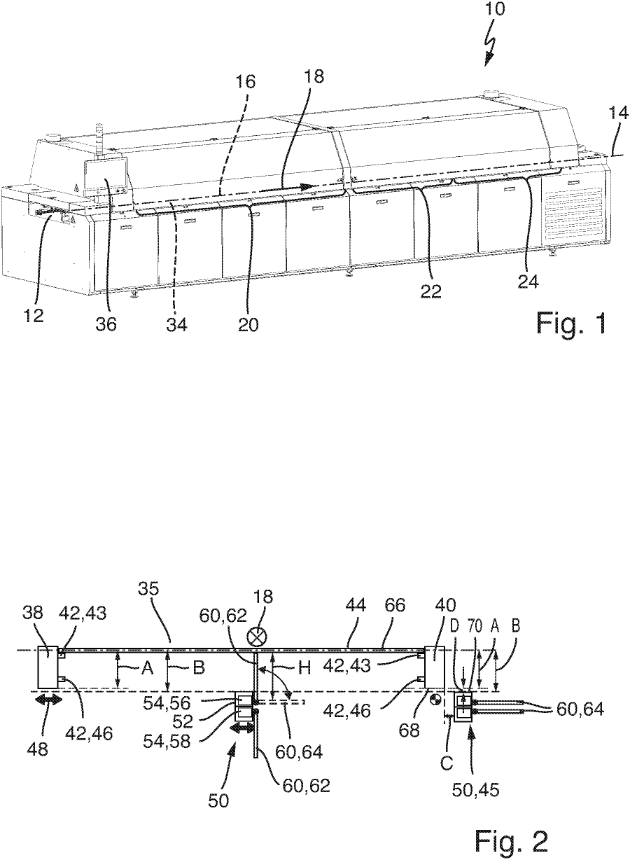

FIG. 1 shows a reflow soldering apparatus 10 for continuously soldering material to be soldered. The reflow soldering apparatus 10 has an entrance 12 and an exit 14, wherein the material to be soldered reaches the reflow soldering apparatus 10 via the entrance 12 and is discharged from the reflow soldering apparatus 10 via the exit 14. The material to be soldered is transported along a transport direction 18 through a process channel 16 indicated in FIG. 1. A preheating zone 20, a soldering zone 22 and a cooling zone 24 are provided in the process channel 16.

A communication unit 36 is provided with a screen and an input device, by means of which communication can occur with a machine controller of the reflow soldering apparatus 10.

The material to be soldered, that is to say the printed circuit board provided with the soldering paste and populated with electronic components, is first heated in the preheating zone 20 to a temperature which is below the melting temperature of the soldering paste. In the soldering zone 22, the printed circuit board is heated for a certain duration to a process temperature which is above the melting point of the soldering paste so that it melts in the soldering zone in order to solder the electronic components to the printed circuit board. In the cooling zone 24, the material to be soldered is cooled so that the liquid solder solidifies before the material to be soldered is removed at the exit 14 of the reflow soldering apparatus 10.

A transport system 34 is provided within the reflow soldering apparatus 10 for transporting the circuit boards along the transport direction 18.

In a cross section of the transport system 34 according to FIG. 2, a transport track 35 with two transport bars 38, 40 is shown, in each of which a conveying means, in particular in the form of a revolving chain or a revolving region, has. On the conveying means, support sections 42 are provided on which the material to be soldered, i.e. the printed circuit board 44, rests in the feed 43. Since the support sections 42 move in the direction of transport 18 in the feed 43, the material to be soldered 44 is ultimately transported in the transport direction 18. The return 46 can be seen in the lower region of the transport bars 40 where the support sections 42 are moved counter to the transport direction 18. In the embodiment shown in FIG. 2, the transport bar 40 is arranged rigidly within the soldering apparatus, and the transport bar 38 is contrastingly adjustable in the transverse direction 48 and adaptable to the width of the material to be soldered 44.

In FIG. 2, a middle support 50 is shown in the middle region between the two transport bars 38 and 40, which middle support 50 comprises a middle bar 52 in which a circulating conveying means 54, in particular a chain or a belt, is provided, the feed 56 of which middle support is moved in the transport direction 18 synchronously with the feed 43 of the support sections 42 of the transport bars 38, 40. In the middle bar 52, the return 58 of the conveying means 54 directed counter to the transport direction 18 is shown below the feed 56.

As is clear from FIG. 2, folding elements 60 are provided on the conveying means 54, which folding elements each laterally contact the conveying means 54. The folding elements 60 can be moved between a support position 62 shown in FIG. 2 at the feed 56, in which the folding elements 60 are arranged running in the vertical direction for supporting the material to be soldered 44, and a folded position 64, in which the folding elements 60 are folded in the horizontal direction. In the middle region of FIG. 2, the folded position 64 of a folding element 60 is indicated by dashed lines.

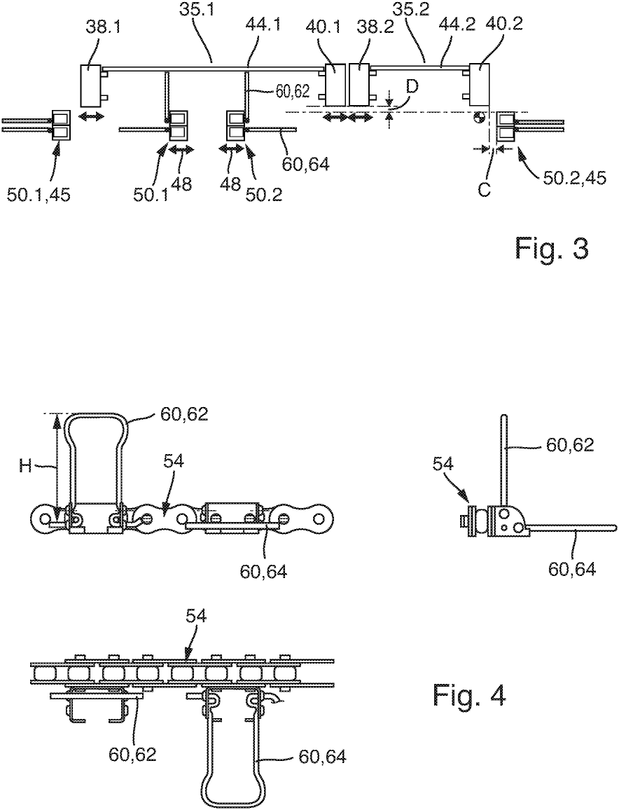

In the case in which a middle support 50 for supporting a circuit board 44 is not needed, the middle support 50, as also shown in FIG. 2, can be moved horizontally in the transverse direction 48. To this end, the folding elements 60 are first displaced into the folded position 64. The middle support 50 can then be moved in the horizontal direction so far in the transverse direction 48 by means of an adjusting device, which is not shown in FIGS. 2 and 3, that the middle support 50 can be moved underneath the transport bar 40 into a parked position 45 which is provided laterally next to the transport bars 40. In order to enable this, the design is such that the distance A between a transport plane 66 within which the printed circuit board 44 lies and the underside 68 of the transport bars 38, 40 facing away from the transport plane 66 is smaller than the distance B between the transport plane 66 and an upper side 70 of the middle support 50 facing the transport plane 66.

In the parked position 45, the middle support 50 has a distance C from the transport bar 68 in the horizontal direction and a distance D from the transport bar 68 in the vertical direction. This ensures that, in a soldering process in which the middle support 50 is in the parked position 45, no negative impairment of the heat conduction towards the printed circuit board takes place.

Suitable adjusting devices for adjusting the transport bar 38 and/or the middle support 50 in the transverse direction 48 are, for example, threaded spindles or toothed racks extending in the transverse direction which are known from the prior art.

In the embodiment according to FIG. 3, two transport tracks 35.1 and 35.2 are provided, wherein printed circuit boards 44.1 and 44.2 can be transported through the soldering apparatus 10 in each of the transport tracks 35.1 and 35.2. Since the printed circuit boards 44 to be soldered are of different widths, the two transport tracks 35.1 and 35.2 have a different width. Each of the transport tracks 35.1 and 35.2 has two transport bars 38.1 and 40.1 as well as 38.2 and 40.2. As can be seen in FIG. 3, a total of two middle supports 50.1 and 50.2 are provided, which are used in FIG. 3 for supporting the printed circuit board 44.1 and 44.2. The design of the middle supports 50.1 and 50.2 corresponds to the design of the middle support 50 according to FIG. 2.

The two middle supports 50.1 and 50.2 are adjustable independently of one another in the transverse direction 48 via adjusting devices (not shown). The transport bars 38.1, 40.1 and 38.2 are also adjustable in the transverse direction. Only the transport bar 40.2 is rigidly arranged in the soldering apparatus 10.

The arrangement of the two middle supports 50.1 and 50.2 and the design of the adjusting devices is such that both middle supports 50.1 and 50.2, as shown in FIG. 3, can support the printed circuit board 44.1 or 44.2. However, it is also conceivable that the middle support 50.2 or 50.1 is adjustable in the transverse direction so far that it supports only the printed circuit board 44.2 or 44.1. Due to the fact that the middle supports 50.1 and 50.2 are arranged at a distance from the transport bars 38.1, 40.1 and 38.2, 40.2 in the horizontal direction, they can be moved freely below the transport bars 38.1, 40.1 and 38.2, 40.2.

In this respect, the two middle supports 50.1 or 50.2 – when they are not needed – can be displaced into a right or left parked position 45, as shown on the right and left in FIG. 3, in which they are at a distance from the particular transport bar 38.1 or 40.2 in the horizontal direction. The two middle supports 50.1 and 50.2 are then each located outside the region of the particular printed circuit board 44.1, or 44.2 below the two transport tracks 35.1 and 35.2. The printed circuit boards 44.1 and 44.2 can then be heated by means of heating elements (not shown) without such heating being adversely affected by the middle supports 50.1 and 50.2, for example by shielding or a shadow effect. Before displacing the middle supports 50.1 and 50.2 into the parked position 45, at least the folding elements 60 of the feed 56 are displaced from their support position into the folded position, as shown in FIG. 3 on the right and left.

In order to displace the folding elements 60 into the particular support position or folded position, it is conceivable that one or more folding devices (not shown in the figures) are provided. The particular folding device is in particular such that, shortly before or during the movement of the middle support 50 into the parked position 45, the folding elements 60 are moved into the folded position at least in the feed 56. It is also advantageously provided that the folding elements 60 are always in the folded position in the return.

FIG. 4 shows a detail of the conveying means 54, which is designed as a chain, in side view, in plan view, and in cross section, as it may be used in the middle support 50. Folding elements 60 in the form of folding spring tabs are provided that laterally contact the conveying means 54. The folding spring tabs are formed from bent wire sections and can be displaced between the support position 62, in which the folding elements 60 extend in the vertical direction, and the folded position 62, in which they are located essentially in a horizontal position, by means of a folding device (not shown). The height H of the folding elements 60 is greater than the distance B and, in the shown embodiment, also greater than the distance B, and is dimensioned such that the free end of the folding elements 60 serves to support the printed circuit board 44 in the support position.

According to the invention, further arrangements (not shown in the figures) are conceivable. In particular, it is conceivable to provide a third transport track and a third middle support for the third transport track. The three middle supports are then preferably arranged in such a way that all middle supports can be moved independently of one another in the transverse direction, so that, for example, two or all three middle supports are assigned to a transport track, or all three middle supports can be moved laterally next to the particular transport bar into a parked position.

What is claimed is:

1. A transport system for transporting material to be soldered through a soldering apparatus, with at least one transport track extending in the transport direction in which the material to be soldered is transportable in a transport plane in the transport direction, wherein the transport track comprises two transport bars extending in the transport direction and at least one middle support with a middle bar extending in the transport direction, wherein the middle bar has a revolving conveying means with folding elements, wherein the conveying means provides a feed in the transport direction and a return counter to the transport direction, and wherein the folding elements are displaceable between a support position and a folded position, and with an adjusting device for transverse adjustment of the at least one middle support in a transverse direction running transversely to the transport direction, characterized in that a distance A between an underside of at least one transport bar facing away from the transport plane and the transport plane is smaller than a distance B between an upper side of the at least one middle support facing the transport plane and the transport plane, and that the adjustment device is designed such that the middle support with folding elements is movable in the folded position in the transverse direction underneath the at least one transport bar into a parked position provided laterally next to the transport bar.

2. The transport system according to claim 1, characterized in that the middle support is arranged in the parked position in the horizontal direction and/or in the vertical direction at a distance (C, D) from the transport bar underneath which it is moved into the parked position.

3. The transport system according to claim 1, characterized in that two or more transport tracks are provided, and a middle support is provided for each of the transport tracks, wherein each of the middle supports is adjustable in the transverse direction with an adjusting device independently of the other middle support such that each of the middle supports can be moved into a parked position.

4. The transport system according to claim 1, characterized in that two or more transport tracks are provided, and a middle support is provided for each of the transport tracks, wherein each of the middle supports is adjustable in the transverse direction with an adjusting device independently of the other middle support such that the individual middle supports are each provided in a separate transport track or together in one of the two transport tracks for supporting the particular material to be soldered.

5. The transport system according to claim 1, characterized in that two middle supports are provided, and the folding elements of the particular middle supports laterally contact the particular conveying means, wherein the folding elements of the two conveying means are each provided on sides facing away from one another or on sides facing one another of the two middle supports.

6. The transport system according to claim 1, characterized in that, in the parked position, the folding elements are in the folded position in the feed and/or in the return.

7. The transport system according to claim 1, characterized in that at least one folding device is provided for displacing the folding elements between the support position and the folded position.

8. The transport system according to claim 7, characterized in that the at least one folding device is configured such that, before or during the movement of the at least one middle support into the parked position, the folding elements are in the folded position at least in the feed.

9. The transport system according to claim 7, characterized in that the at least one folding device is configured such that the folding elements are in the folded position in the return.

10. A soldering apparatus in which material to be soldered can be transported along a transport direction, comprising a transport system for transporting the material to be soldered through the soldering apparatus, with at least one transport track extending in the transport direction in which the material to be soldered is transportable in a transport plane in the transport direction, wherein the transport track comprises two transport bars extending in the transport direction and at least one middle support with a middle bar extending in the transport direction, wherein the middle bar has a revolving conveying means with folding elements, wherein the conveying means provides a feed in the transport direction and a return counter to the transport direction, and wherein the folding elements are displaceable between a support position and a folded position, and with an adjusting device for transverse adjustment of the at least one middle support in a transverse direction running transversely to the transport direction, characterized in that a distance A between an underside of at least one transport bar facing away from the transport plane and the transport plane is smaller than a distance B between an upper side of the at least one middle support facing the transport plane and the transport plane, and that the adjustment device is designed such that the middle support with folding elements is movable in the folded position in the transverse direction underneath the at least one transport bar into a parked position provided laterally next to the transport bar.
